(19) United States
(12) Patent Application Publication
(10) Pub. No.: US 2018/0202945 A1
(43) Pub. Date: Jul. 19, 2018

(54) SEMICONDUCTOR MANUFACTURING APPARATUS AND SEMICONDUCTOR MANUFACTURING METHOD

(71) Applicant: Renesas Electronics Corporation, Tokyo (JP)

(72) Inventors: Naoto KANZAKI, Hitachinaka-shi (JP); Kotaro Horikoshi, Hitachinaka-shi (JP); Toru Shinaki, Hitachinaka-shi (JP)

(21) Appl. No.: 15/839,583

(22) Filed: Dec. 12, 2017

(30) Foreign Application Priority Data
Jan. 18, 2017 (JP) 2017-006408

(51) Int. Cl. G01N 21/956; H01L 21/3065; H05H 1/46; H01L 21/683; H01L 21/687; H01L 21/764

(52) U.S. Cl. CPC G01N 21/956; H01L 21/3065; H01L 21/764; H01L 21/6833; H01L 21/687; H05H 1/46

(57) ABSTRACT

A semiconductor manufacturing apparatus includes: an electrostatic chuck that is installed in a chamber and over which a semiconductor wafer to be subjected to plasma processing is to be mounted; and an observation device for observing a change in a signal waveform occurring in the electrostatic chuck during the plasma processing. The observation device determines abnormal discharge in a processing chamber based on a change pattern of the signal waveform.

### CROSS-REFERENCE TO RELATED APPLICATIONS

The disclosure of Japanese Patent Application No. 2017-006408 filed on Jan. 18, 2017 including the specification, drawings and abstract is incorporated herein by reference in its entirety.

### BACKGROUND

The present invention relates to a semiconductor manufacturing apparatus and a semiconductor manufacturing method, and to a semiconductor manufacturing apparatus for performing etching by, for example, plasma processing and a semiconductor manufacturing method using the semiconductor manufacturing apparatus.

Semiconductor manufacturing steps include an etching step in which, in order to couple, for example, a wiring layer (wiring film) formed over a semiconductor wafer (hereinafter, also referred to as a semiconductor substrate) with a pad electrode, a via is formed in an insulating layer (insulating film) formed above the wiring layer. In the etching step, the insulating layer is etched by, for example, plasma processing, and an opening is formed in the insulating layer to form the via. The wiring layer is coupled to the pad electrode through the via by embedding a conductive layer (conductive film) serving as the pad electrode in this via.

In an etching apparatus for performing etching by plasma processing, a semiconductor wafer is placed in a chamber (hereinafter, also referred to as a processing chamber), and an insulating layer is etched by plasma generated by applying a high-frequency voltage between plasma electrodes.

Apparatuses using plasma are described, for example, in Patent Documents 1 to 5.

### RELATED ART DOCUMENT

### Patent Document

[Patent Document 1] Japanese Unexamined Patent Application Publication No. 2001-319922

[Patent Document 2] Japanese Unexamined Patent Application Publication No. 2002-324783

[Patent Document 3] Japanese Unexamined Patent Application Publication No. 2003-163200

[Patent Document 4] Japanese Unexamined Patent Application Publication No. 2005-259941

[Patent Document 5] Japanese Unexamined Patent Application Publication No. 2007-214254

### SUMMARY

Each of Patent Documents 1 to 5 describes a technique for detecting abnormal discharge in an apparatus using plasma. That is, Patent Document 1 describes that abnormal discharge is detected by light emission. Patent Document 2 describes that abnormal discharge is detected by amplitude modulation of applied high-frequency voltage/current. Further, Patent Document 3 describes that abnormal discharge is detected by a change in applied high-frequency voltage/current/phase. Patent Document 4 describes that abnormal discharge is detected by a voltage change in any one of a high-frequency load voltage, a high-frequency chain voltage, and an electrode voltage, the last three voltages showing an operation state of matching for suppressing a reflected wave to a traveling wave. Furthermore, Patent Document 5 describes that abnormal discharge is detected by a voltage change in a position voltage of the variable capacity of a matching box.

In the chamber of an etching apparatus using plasma, a deposition (reaction product) is generated by plasma, which attaches to the inner surface of the chamber. The attached deposition is peeled irregularly. When scattered over a semiconductor wafer as a foreign matter, the peeled deposition causes a defect in a semiconductor device (product). Because a deposition is peeled irregularly, a foreign matter remains in the chamber for a certain period of time, which may reduce the yield of the subsequent semiconductor wafers.

Based on the knowledge that abnormal discharge occurs when a deposition is peeled, the present inventors have thought that a reduction in the yield of semiconductor wafers is suppressed by a new configuration and method not described in any of Patent Documents 1 to 5.

Other problems and new characteristics will become clear from the description and accompanying drawings of the present specification.

A semiconductor manufacturing apparatus according to one embodiment includes: a processing table that is installed in a processing chamber and over which a semiconductor substrate to be subjected to plasma processing is mounted; and an observation device for observing a change in a signal waveform occurring over the processing table during the plasma processing. Herein, the observation device determines abnormal discharge in the processing chamber based on the change pattern of the signal waveform.

According to the one embodiment, it is possible to provide a semiconductor manufacturing apparatus and a semiconductor manufacturing method capable of suppressing a reduction in yield.

### BRIEF DESCRIPTION OF THE DRAWINGS

FIG. 1 is a sectional view illustrating a configuration of a semiconductor manufacturing apparatus according to First embodiment;

FIGS. 2A and 2B are views for explaining a susceptor according to First Embodiment;

FIG. 3 is an explanatory view illustrating three types of abnormal discharge according to First Embodiment;

FIGS. 4A to 4C are explanatory views illustrating abnormal discharge according to First Embodiment;

FIGS. 5A to 5C are explanatory views for explaining the operation of an observation device according to First embodiment;

FIG. 6 is a waveform view schematically illustrating signal waveforms observed in an observation device according to First Embodiment;

FIG. 7 is a block view illustrating the functions of an observation device according to First Embodiment;

FIGS. 8A to 8C are sectional views illustrating a semiconductor manufacturing method according to Second Embodiment;

FIGS. 9A to 9C are sectional views illustrating a semiconductor manufacturing method according to Second Embodiment; and

FIGS. 10A to 10C are sectional views illustrating a semiconductor manufacturing method according to Second Embodiment.

### DETAILED DESCRIPTION

Hereinafter, each embodiment of the present invention will be described with reference to the drawings. It should be noted that the disclosure is merely one example and appropriate modifications that can be easily conceived of by those skilled in the art, while the gist of the invention is kept, naturally fall within the scope of the invention. Further, in the drawings, the width, thickness, shape, or the like of each part may be more schematically illustrated than the actual form for clearer description, but it is merely one example and the interpretation of the invention should not be limited.

Furthermore, in this specification and each drawing, the same reference numerals are given to the same elements as those previously described with reference to the preceding drawings, and detailed description may be omitted appropriately.

### First Embodiment

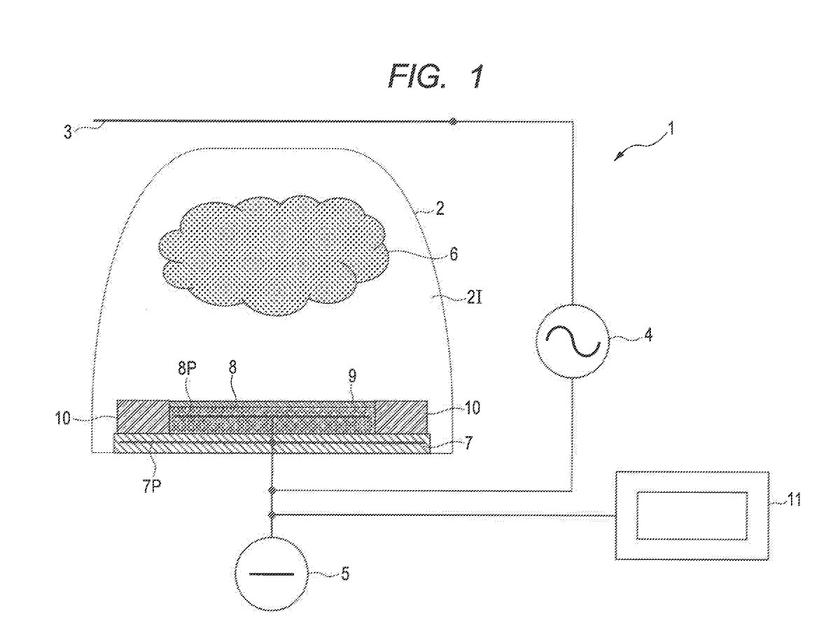

FIG. 1 is a sectional view illustrating a configuration of a semiconductor manufacturing apparatus according to First Embodiment. Herein, an etching apparatus for performing etching processing by using plasma will be described as an example of the semiconductor manufacturing apparatus. In the view, the reference numeral 1 indicates an etching apparatus (semiconductor manufacturing apparatus). The etching apparatus 1 includes a chamber 2, a plasma high-frequency power supply 4, an electrostatic chuck power supply 5, and an observation device 11. FIG. 1 illustrates a state where etching processing is being performed on a semiconductor wafer.

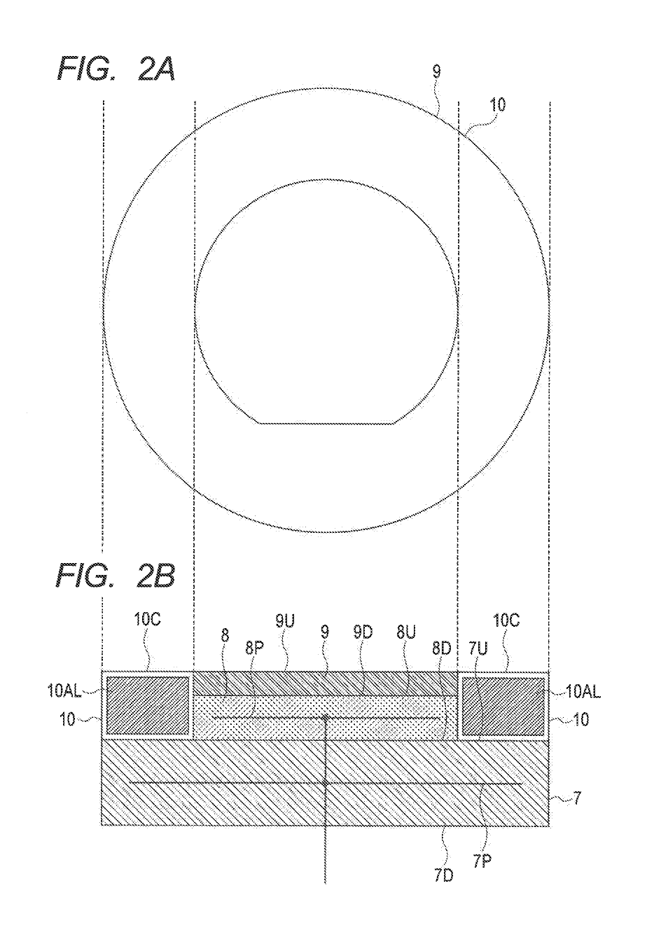

In the state where etching processing is being performed, a semiconductor wafer 9 is moved over a wafer stage 7 installed in an inside 2I of the chamber 2. Further, an electrostatic chuck 8 arranged over the main surface of the wafer stage 7 adsorbs the semiconductor wafer (semiconductor substrate) 9. Although described later with reference to FIG. 2, a susceptor 10 is arranged over the main surface of the wafer stage 7 so as to surround the semiconductor wafer 9, when viewed from the main surface side of the semiconductor wafer 9. During the etching processing, the chamber 2 is hermetically sealed such that the wafer stage 7, the electrostatic chuck 8, the semiconductor wafer 9, and the susceptor 10 are sealed in the inside 2I thereof.

When the etching processing is completed, the semiconductor wafer 9 is moved from the wafer stage 7 to the outside of the chamber 2. Although not illustrated in the view, the chamber 2 is provided with a gas suction port for filling the inside 2I thereof with gas and a discharge port for discharging the gas.

In this First Embodiment, one plasma electrode 7P of a pair of plasma electrodes (e.g., coil-shaped electrodes) is provided inside the wafer stage 7 and the other plasma electrode 3 is arranged outside the chamber 2. The plasma high-frequency power supply 4 is coupled to the pair of the plasma electrodes 3 and 7P, and during the etching processing, a high-frequency voltage is supplied from the plasma high-frequency power supply 4 to the pair of the plasma electrodes 3 and 7P. Due to the potential difference between the pair of the plasma electrodes 3 and 7P, plasma 6 is generated in the inside of 2I of the chamber 2, and a predetermined portion of the semiconductor wafer 9 is etched by the generated plasma 6.

The electrostatic chuck 8 is provided with an electrostatic chuck electrode 8P. The electrostatic chuck power supply 5 is coupled to the electrostatic chuck electrode 8P, and a DC voltage is supplied from the electrostatic chuck power supply 5 to the electrostatic chuck electrode 8P. With a DC voltage being supplied, a charge is generated in the semiconductor wafer 9 and a Coulomb force or the like is generated between the electrostatic chuck 8 and the semiconductor wafer 9, whereby the back surface of the semiconductor wafer 9 is adsorbed to the main surface of the electrostatic chuck 8.

In this First Embodiment, although not particularly limited, the plasma electrode 7P and the electrostatic chuck electrode 8P are electrically coupled together, and a plasma high-frequency voltage (second voltage) and an electrostatic chuck DC voltage (first voltage) are supplied to the two electrodes. The electrostatic chuck electrode 8P and the plasma electrode 7P are coupled to the observation device 11.

During the etching processing, the observation device 11 observes changes in signal waveforms occurring at the electrostatic chuck electrode 8P and the plasma electrode 7P, and outputs observation results. In order to eliminate cyclic changes in the plasma high-frequency voltage at the plasma electrode 7P, the observation device 11 can be regarded as functionally having a filter for suppressing the transmission of the cyclic voltage changes. In FIG. 1, this functional filter is illustrated as a box inside the observation device 11.

The chamber 2 is made of, for example, aluminum, and alumite is formed as a film over the inner surface facing the inside 2I. Similarly, the susceptor 10 is also made of aluminum, and alumite is formed as a film over the surface thereof. Of course, the films formed over these surfaces are not limited to alumite, and may be formed of yttrium. Also, the materials that form the chamber 2 and the susceptor 10 are not limited to aluminum. A deposition produced by plasma processing grows while depositing over the films. As the growth progresses, it is peeled, and for example, falls, and becomes a foreign matter in the inside 2I of the chamber 2.

When a deposition falls during the etching processing, abnormal discharge occurs between the deposition and the chamber 2 or the plasma 6. Also, when a deposition is peeled and the film over the inner surface of the chamber 2 or/and the film of the susceptor 10 is/are exposed, abnormal discharge occurs between the exposed portion and the plasma 6. In this case, the exposed portion is etched by the plasma 6, whereby a foreign matter is generated. The yield of the semiconductor wafer 9 is reduced with a foreign matter being generated in this way.

Further, when the film formed over the inner surface of the chamber 2 or/and that formed over the surface of the susceptor 10 is/are peeled, aluminum that forms the chamber 2 or/and the susceptor 10 is exposed, and also in this case abnormal discharge occurs between the exposed portion and the plasma 6, whereby a foreign matter is generated.

Furthermore, if the susceptor 10 is not properly attached, abnormal discharge occurs between the susceptor 10 and, for example, the wafer stage 7. As will be described with reference to FIG. 2, if the susceptor 10 is not properly attached, the amount of etching in the semiconductor wafer 9 varies, which also leads to a reduction in the yield of the semiconductor wafer 9.

FIGS. 2A and 2B are views for explaining the susceptor 10 according to First Embodiment, in which: FIG. 2A is a plan view illustrating a state where the semiconductor wafer 9 and the susceptor 10 are mounted over the wafer stage 7; and FIG. 2B is a sectional view illustrating the state where they are mounted over the wafer stage 7.

The wafer stage 7 has a main surface 7U and a back surface 7D facing the main surface, and the plasma electrode 7P is arranged between the main surface 7U and the back surface 7D. The electrostatic chuck 8 also has a main surface 8U and a back surface 8D facing the main surface, and the electrostatic chuck electrode 8P is arranged between the main surface 8U and the back surface 8D. The electrostatic chuck 8 is to be mounted over the wafer stage 7 such that the back surface 8D of the electrostatic chuck 8 faces the main surface 7U of the wafer stage 7. With electrostatic chuck power supply being supplied to the electrostatic chuck electrode 8P, the back surface 9D of the semiconductor wafer 9 is adsorbed to the main surface 8U of the electrostatic chuck 8. The back surface 9D and the main surface 8U are illustrated to be in close contact with each other in the view, but there may be a gap therebetween.

The susceptor 10 is provided with a housing part 10AL made of aluminum and a film (alumite film) 10C formed over the surface of the housing part 10AL. As illustrated in FIG. 2A, the susceptor 10 has an inner shape that is the same as the outer shape of the semiconductor wafer 7, and when viewed from the main surface 9U side of the semiconductor wafer 9, the semiconductor wafer 9 is adsorbed such that the outer shape thereof matches the inner shape of the susceptor 10. The susceptor 10 is to be mounted such that the surface thereof is in close contact with the main surface 7U of the wafer stage 7. When mounted, the susceptor 10 is arranged such that the main surface 9U of the semiconductor wafer 9 and the upper surface of the susceptor 10 match each other, as illustrated in FIG. 2B. That is, it is arranged such that when the semiconductor wafer 9 is adsorbed, the upper surface of the susceptor 10 extends along the main surface 9U of the semiconductor wafer 9.

As a result, the susceptor 10, extending at the same height as that of the semiconductor wafer 9, is also arranged in the outer periphery of the semiconductor wafer 9. When the susceptor 10 is not arranged, a step is generated at the outer periphery of the semiconductor wafer 9, whereby a difference occurs in the amount of etching between, for example, a central portion and an outer peripheral portion of the semiconductor wafer 9. On the other hand, it is possible by providing the susceptor 10 to prevent a step from occurring in the outer periphery of the semiconductor wafer 9, whereby the fear that a difference in the amount of etching may be generated can be reduced.

The electrostatic chuck 8 for adsorbing the semiconductor wafer 9 can be regarded as a processing table over which the semiconductor wafer 9 is to be mounted. In addition, because the electrostatic chuck 8 is mounted over the wafer stage 7, a processing table, over which the semiconductor wafer 9 is to be mounted, can also be regarded as being composed of the wafer stage 7 and the electrostatic chuck 8. In this case, the susceptor 10 can also be regarded as being mounted over the processing table.

### <Abnormal Discharge Mode>

It has already been described that the yield of the semiconductor wafer 9 is reduced due to abnormal discharge, however, in this First Embodiment, the occurring abnormal discharge is classified into three types of modes, and estimation of a cause corresponding to each abnormal discharge mode and a coping method are presented.

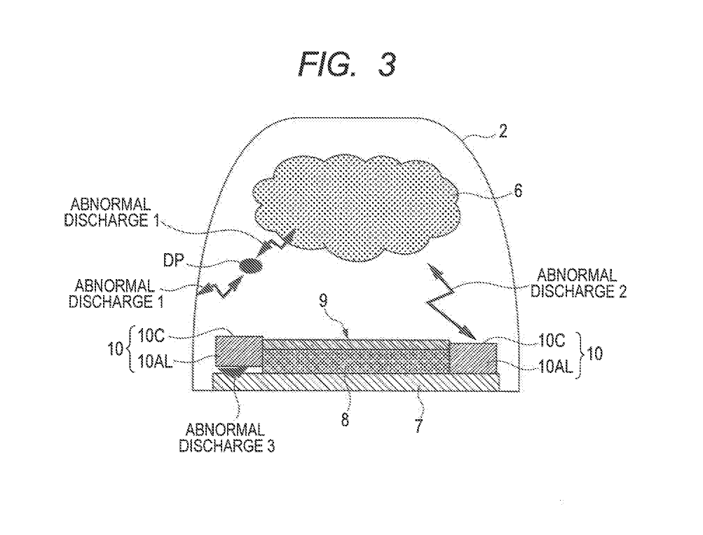

FIG. 3 is an explanatory view for illustrating three types of abnormal discharge according to First Embodiment. FIG. 3 is similar to FIGS. 1, 2A and 2B, but the plasma electrodes 3 and 7P, the electrostatic chuck electrode 8P, the plasma power supply 9, the electrostatic chuck power supply 5, and the observation device 11 are omitted. In FIG. 3, DP indicates a deposition that has been peeled inside the chamber 2. Abnormal discharge 1 occurs between the peeled deposition DP and the plasma 6 or/and the chamber 2. The abnormal discharge caused by the peeled deposition DP, as described above, is referred to as abnormal discharge mode 1 in the present specification. In this case, the peeling includes not only peeling from the inner surface of the chamber 2 but also that of a deposition deposited over the susceptor 10.

The susceptor 10 is attached such that the surface thereof is in close contact with the upper surface 7U of the wafer stage 7, as illustrated in FIG. 2; however, if the susceptor 10 is wrongly attached, a gap may be generated between the lower surface of the susceptor 10 and the main surface 7U of the wafer stage 7. In this case, abnormal discharge 3 occurs between the susceptor 10 and the wafer stage 7. The abnormal discharge caused by wrong attachment of a component, as described above, is referred to as abnormal discharge mode 3 in the present specification.

As illustrated in FIG. 2B, the alumite film 10C is formed over the surface of the aluminum 10AL that forms the susceptor 10. The susceptor 10 is deteriorated due to, for example, aging or the like, and the film formed over the surface thereof may be scraped off. In this case, abnormal discharge 2 occurs between the portion (a portion of the aluminum 10AL) exposed by the film 10C being scraped and the plasma 6. The abnormal discharge 2 caused by the deterioration of a component, as described above, is referred to as abnormal discharge mode 2 in the present specification. FIG. 3 illustrates an example in which the susceptor 10 is taken as a component, but the component is not limited to a susceptor. The film formed over the inner surface of the chamber 2 may be scraped, for example, due to the deterioration of the chamber 2. In this case, the abnormal discharge 2 occurs between a portion of the chamber 2 where the film is scraped and the plasma 6.

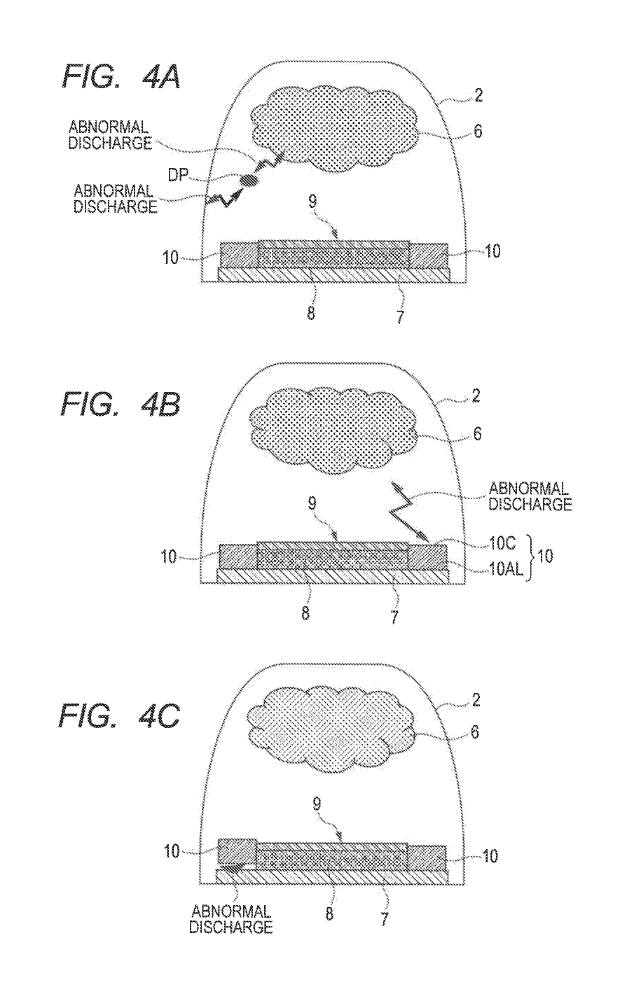

In FIG. 3, three types of the abnormal discharge modes 1 to 3 are illustrated in one view, but these abnormal discharge modes 1 to 3 are separately illustrated in FIGS. 4A to 4C, respectively. FIGS. 4A to 4C are explanatory views illustrating the abnormal discharge according to First Embodiment, in which: FIG. 4A is an explanatory view illustrating, of the abnormal discharge 1 to 3 illustrated in FIG. 3, only the abnormal discharge 1 as the abnormal discharge mode 1; FIG. 4B is one illustrating only the abnormal discharge 2 as the abnormal discharge mode 2; and FIG. 4C is one illustrating only the abnormal discharge 3 as the abnormal discharge mode 3. The reference symbols in FIGS. 4A to 4C are the same as those in FIG. 3, so the description thereof will be omitted.

When abnormal discharge of any one of the abnormal discharge modes 1 to 3 occurs, a change occurs in the charge amount in the main surface 9U of the semiconductor wafer 9, the main surface 7U of the wafer stage 7, or/and the surface of the susceptor 10. As the charge amount changes, the voltage at the electrostatic chuck electrode 8P or/and the plasma electrode 7P changes. That is, during the etching processing, a voltage change accompanying the abnormal discharge is superimposed on the electrostatic chuck power supply or/and the plasma high-frequency power supply supplied to these electrodes. In this First Embodiment, the observation device 11 observes the superimposed voltage change.

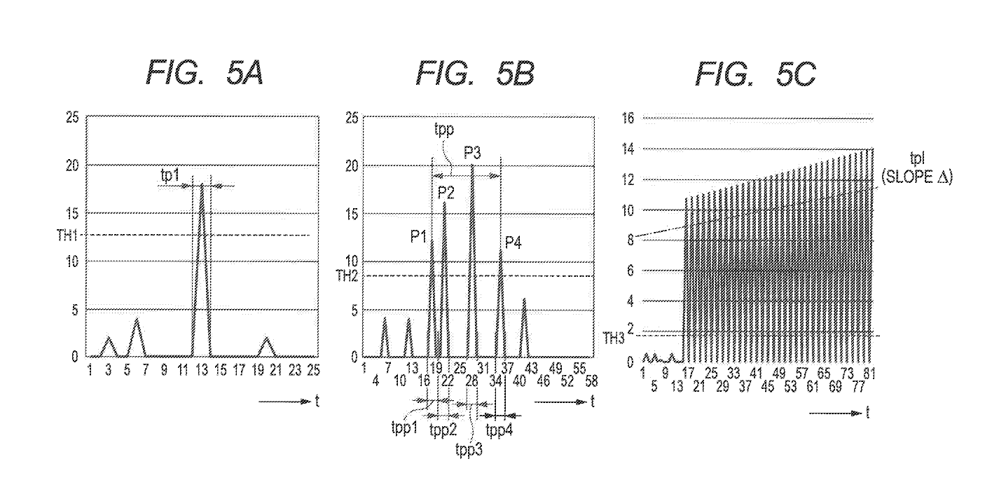

The observation device 11 is provided with the functional filter (FIG. 1), which suppresses the transmission of high-frequency components of the plasma high-frequency voltage, whereby a voltage change caused by the abnormal discharge 1 to 3 is extracted. FIGS. 5A to 5C illustrate the extracted voltage change as a signal waveform. FIGS. 5A to 5C are explanatory views for explaining the operation of the observation device 11 according to First Embodiment.

FIG. 5A illustrates a signal waveform indicating the voltage change extracted in the abnormal discharge mode 1, and FIG. 5B illustrates a signal waveform indicating the voltage change extracted in the abnormal discharge mode 2. FIG. 5C illustrates a signal waveform indicating the voltage change extracted in the abnormal discharge mode 3. In these views, the horizontal axis t represents time. The vertical axis represents voltage or current. Changes at the electrostatic chuck electrode 8P and the plasma electrode 7P caused by abnormal discharge can be grasped as current changes instead of voltage changes, and hence the vertical axis in FIGS. 5A to 5C may represent voltage or current. Therefore, in the present specification, description will be made taking it as a signal change.

The observation device 11 samples signals transmitted via the filter at predetermined intervals. FIGS. 5A to 5C show signal waveforms for sampled one cycle.

In the case of the abnormal discharge mode 1, the deposition DP (FIGS. 3 and 4A) is peeled, and abnormal discharge 1 occurs during a period of time while the peeled deposition DP is falling. Therefore, when the abnormal discharge mode 1 occurs, a signal waveform greatly changes for a predetermined period of time during sampled one cycle. That is, a signal waveform greatly changes in spike shape for a predetermined period of time tp1, as illustrated in FIG. 5A. Therefore, it is possible to determine whether the abnormal discharge mode 1 is occurring, by setting a predetermined threshold value TH1 and observing whether the signal waveform exceeds this threshold value TH1.

In the case of the abnormal discharge mode 2, the abnormal discharge 2 occurs between an exposed portion where the film is scraped and the plasma 6. In this case, a signal waveform greatly changes in spike shape more than once during sampled one cycle. Respective changes in the signal waveform range from several tens ms to several μs. That is, as illustrated in FIG. 5B, when a predetermined threshold value TH2 is set, signal changes each exceeding the threshold value TH2 occur more than once (four times of P1 to P4 in FIG. 5B), and the respective occurrence periods of time tpp1 to tpp4 range from several tens ms to several μs. Therefore, it is possible to determine whether the abnormal discharge mode 2 is occurring, by setting a predetermined observation range time tpp (several s to several μs) and the threshold value TH2 and observing whether a signal waveform exceeds the threshold value TH2 more than once during the observation range time tpp.

In the case of the abnormal discharge mode 3, abnormal discharge occurs between the susceptor 10 wrongly attached and the wafer stage 7. When a plasma high-frequency voltage is supplied in this case, abnormal discharge continually and cyclically occurs according to the frequency of the plasma high-frequency voltage. Therefore, a signal waveform changes in spike shape at a cycle of several tens ms to several μs during sampled one cycle. Further, because charges are accumulated every time the abnormal discharge 3 occurs, the signal waveform rises with the lapse of time. That is, when a predetermined threshold value TH3 is set, the signal waveform changes continually (continuously) so as to exceed the predetermined threshold value TH3, and an envelope tp1, obtained by coupling the peaks of the signal waveform, rises with a slope Δ, as illustrated in FIG. 5C. It is possible to determine whether the abnormal discharge mode 3 is occurring, by observing whether the signal waveform changes beyond the predetermined threshold value TH3 and whether its envelope is rising. When the supply of the plasma high-frequency voltage is stopped, the charges accumulated in the abnormal discharge 3 are discharged, and hence the signal waveform becomes lower than the threshold value TH3.

In each of FIGS. 5A to 5C, the signal waveform has a region where it changes within a range not reaching the corresponding one of the threshold values TH1 to TH3, which shows small abnormal discharge and the like caused by, for example, a small deposition being peeled.

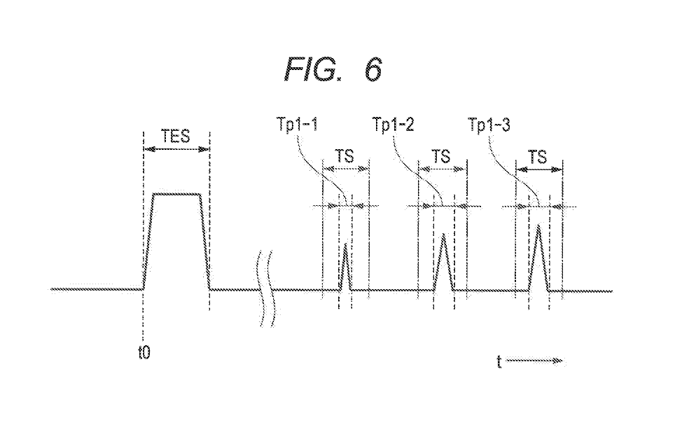

FIG. 6 is a waveform view schematically illustrating signal waveforms observed in the observation device 11 according to First Embodiment during etching processing. Herein, the case where the abnormal discharge mode 1 occurs will be described as an example. In the view, the horizontal axis t represents time and the vertical axis represents the value of a signal waveform.

In the view, a plasma high-frequency voltage is supplied to the plasma electrodes 3 and 7P at time t0. The charge amount greatly changes near the electrostatic chuck 8 and the susceptor 10 when a plasma high-frequency voltage is supplied, and hence the signal waveform observed by the observation device 11 greatly changes during a period of time TES. Thereafter, the observation device 11 compares the threshold value TH1 illustrated in FIG. 5A with the signal waveform in a cyclically repeated sampling period of time TS. FIG. 6 illustrates a state where with the lapse of time, a peeled deposition becomes larger and a change in the signal waveform also becomes larger. Therefore, the period of time during which the signal waveform is changing also gradually becomes longer from Tp1-1 to Tp1-3. That is, deposition of the deposition DP progresses and the abnormal discharge caused by the deposition DP gradually becomes larger, and hence the change in the signal waveform also becomes larger and the period of time gradually becomes longer. When the change in the signal waveform exceeds the threshold value TH1, the observation device 11 determines that abnormal discharge has occurred by the deposition DP.

Also, when the plasma high-frequency power supply is supplied, the signal waveform greatly changes as illustrated in FIG. 6, but the observation device 11 can easily grasp the time (timing) t0 when the plasma high-frequency power supply is supplied, and hence the change can be easily distinguished from the abnormal discharge caused by the deposition DP.

Herein, description has been made taking the abnormal discharge mode 1 as an example, but the abnormal discharge modes 2 and 3 are also similarly determined by observing the signal waveform at a sampling cycle TS in order to determine whether it changes as illustrated in FIGS. 5B and 5C.

In this First Embodiment, the changes in the signal waveform are classified into patterns. That is, the signal waveforms are classified into patterns depending on the shape of the signal waveform changing with time. In this First Embodiment, a signal change occurring beyond any one of the threshold values TH1 to TH3 is determined as a pattern. The case where the signal waveform changes so as to exceed the threshold value TH1 once, as illustrated in FIG. 5A, is classified as an abnormal discharge pattern 1 (first abnormal discharge pattern). The case where the signal waveform changes so as to exceed the threshold value TH2 more than once during the predetermined observation range time tpp, as illustrated in FIG. 5B, is classified as an abnormal discharge pattern 2 (second abnormal discharge pattern). That is, in First Embodiment, when the number of times when the threshold value is exceeded is less than twice (predetermined number of times), it is classified as the abnormal discharge pattern 1, and when the number of times is twice or more, it is classified as the abnormal discharge pattern 2. Further, the case where the signal waveform exceeds the threshold value TH3 more than once and the envelope of the signal waveform rises, as illustrated in FIG. 5C, is classified as an abnormal discharge pattern 3 (third abnormal discharge pattern).

The abnormal discharge patterns 1 to 3 correspond to the abnormal discharge modes 1 to 3, respectively. Therefore, it is possible in the observation device 11 to specify the abnormal discharge mode that is occurring, by comparing the change pattern in the signal waveform with each of the above three types of the abnormal discharge patterns 1 to 3 and by specifying the abnormal discharge pattern that matches. It is possible to estimate a place where abnormal discharge is occurring by specifying the abnormal discharge mode that is occurring.

That is, during etching processing, the signal waveform at the electrostatic chuck electrode 8P and the plasma electrode 7 is classified into any one of the above abnormal discharge patterns 1 to 3 from the change pattern thereof by the observation device 11. With the classification, it is possible to estimate a place where abnormal discharge is occurring.

If the change pattern of the signal waveform matches the abnormal discharge pattern 1, it is determined that the abnormal discharge mode 1 is occurring, and it can be assumed that abnormal discharge is occurring due to a foreign matter caused by the deposition DP in the inside 2I of the chamber 2. If the change pattern matches the abnormal discharge pattern 3, it is determined that the abnormal discharge mode 3 is occurring, and it can be assumed that abnormal discharge is occurring due to wrong attachment of a component. Further, if the change pattern matches the abnormal discharge pattern 2, it is determined that the abnormal discharge mode 2 is occurring, and it can be assumed that abnormal discharge is occurring due to the deterioration of the chamber 2 or/and a component.

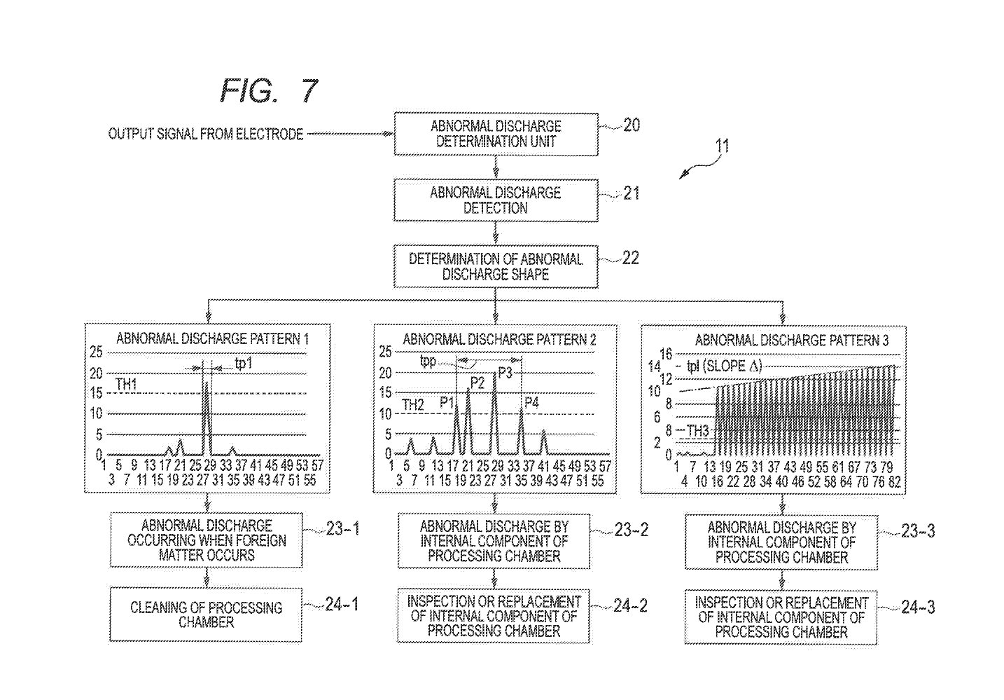

FIG. 7 is a block view illustrating the functions of the observation device 11 according to First Embodiment. When etching processing is being performed, signals (output signals) at the electrodes (the electrostatic chuck electrode 8P and the plasma electrode 7P) are supplied to the observation device 11. The observation device 11 includes an abnormal discharge determination unit 20. This abnormal discharge determination unit 20 has the function of the filter illustrated in FIG. 1. The abnormal discharge determination unit 20 detects the presence or absence of abnormal discharge (abnormal discharge detection 21) based on the supplied output signals. The presence or absence of abnormal discharge is detected, for example, by determining whether a signal waveform, generated by removing a high-frequency component of the plasma high-frequency voltage with the filter, exceeds a predetermined threshold value voltage.

When abnormal discharge is detected, the determination 22 of the abnormal discharge shape is performed. That is, it is determined which one of the above three types of the abnormal discharge patterns 1 to 3 the change pattern of the signal waveform, generated by removing a high-frequency component, matches. In this case, for example, in the signal waveform from which a high-frequency component has been removed, it is determined which one of the above three types of the abnormal discharge patterns 1 to 3 the region of a waveform exceeding the threshold values TH1 to TH3 matches. That is, it is determined whether both the patterns match each other in the region exceeding any one of the threshold values TH1 to TH3. When determining that the change pattern of the signal waveform matches the abnormal discharge pattern 1 (left side in the view), the observation device 11 assumes that the occurring abnormal discharge is caused by a foreign matter. That is, the observation device 11 assumes as abnormal discharge 23-1 due to occurrence of a foreign matter, and presents cleaning 24-1 of the processing chamber (the inside 2I of the chamber 2).

When determining that the change pattern of the signal waveform matches the abnormal discharge pattern 2 (center in the view), the observation device 11 assumes as abnormal discharge 23-2 caused by a component installed in the inside of the processing chamber (the inside 2I of the chamber). In this case, the observation device 11 presents inspection or replacement 24-2 of an internal component of the processing chamber.

Further, when determining that the change pattern of the signal waveform matches the abnormal discharge pattern 3 (right side in the view), the observation device 11 assumes as abnormal discharge 23-3 caused by a component installed in the inside the processing chamber (the inside 2I of the chamber). In this case, the observation device 11 presents inspection or replacement 24-3 of an internal component of the processing chamber.

In FIG. 7, the measures (coping measures) presented by the observation device 11 are the same as each other in the abnormal discharge patterns 2 and 3, but more detailed measures may be presented. For example, when the change pattern matches the abnormal discharge pattern 3, the observation device may present confirmation of a defect in a component, and when the change pattern matches the abnormal discharge pattern 2, the observation device may present confirmation of the deterioration of the chamber 2 or a component such as the susceptor 10.

Further, the observation device 11 may display only the determined abnormal discharge pattern or only a place where abnormal discharge, as indicated by one of 23-1 to 23-3, is occurring. In this case, a user may consider a measure after confirming the display content of the observation device.

According to First Embodiment, it is possible to grasp, in a distinguished way, deposition peeling, a defect in a component such as the susceptor 10, and deterioration (inner surface of a chamber and peeling of the film of a component) from a signal waveform based on signal changes at the electrostatic chuck electrode 8P and the plasma electrode 7P, whereby it is possible to promptly implement a measure corresponding to each of the abnormal discharge patterns, as described above.

The case where when abnormal discharge occurs, a measure corresponding to each of the abnormal discharge patterns is presented has been described, but the present invention is not limited thereto. For example, when anyone of the above three types of the abnormal discharge patterns continues, it is better only to stop the etching apparatus, or only to stop or interrupt etching processing for a new semiconductor wafer.

The abnormal discharge patterns 1 to 3 illustrated in FIG. 7 are the same as those in FIGS. 5A to 5C, and hence the description thereof will be omitted.

The above threshold values TH1 to TH3 may be determined by, for example, a user performing etching processing with the etching apparatus 1 and based on a signal waveform (a high-frequency component is removed) output during each etching processing. The threshold value TH1 may be determined such that, for example, etching processing, in which the abnormal discharge mode 1 occurs, is performed more than once and the change pattern of the signal waveform obtained in each processing matches the abnormal discharge pattern 1. Similarly, the threshold value TH2 may be determined such that etching processing, in which the abnormal discharge mode 2 occurs, is performed more than once and the change pattern matches the abnormal discharge pattern 2. Further, the threshold value TH3 may be determined such that etching processing, in which the abnormal discharge mode 3 occurs, is performed more than once and the change pattern matches the abnormal discharge pattern 3. Therefore, the threshold values TH1 to TH3 to be determined may or may not be the same as each other.

Herein, an example, in which abnormal discharge patterns are classified into three types of the abnormal discharge patterns 1 to 3, has been described, but the present invention is not limited thereto. Abnormal discharge patterns may be classified, for example, into two types or four or more types.

A change in the signal waveform based on the signal changes at the electrostatic chuck electrode 8P and the plasma electrode 7P can be regarded as noise superimposed on the voltage or current supplied from the electrostatic chuck power supply 5 and the plasma high-frequency power supply 4. For example, each of the signal changes illustrated in Figs. 5A to 5C can be regarded as spike noise. In this case, the abnormal discharge patterns 1 and 2 can be regarded as being determined by the number of spike noise exceeding the threshold values TH1 and TH2 and the period of the spike noise. The abnormal discharge pattern 3 can be regarded as being determined by the shape of the envelope tp1 formed by a plurality of spike noise each having a predetermined period of time and exceeding the threshold value TH3.

In First Embodiment, an example, in which a change in the signal waveform based on the signal changes at both of the electrostatic chuck electrode 8P and the plasma electrode 7P is observed, has been described, but it may be configured to observe a change in the signal waveform based on the signal change at either of the electrodes. That is, only one of the electrostatic chuck electrode 8P and the plasma electrode 7P may be coupled to the observation device 11.

### Second Embodiment

A method of manufacturing a semiconductor device (semiconductor manufacturing method) using the etching apparatus 1 according to First Embodiment will be described.

The etching apparatus is used in a plurality of etching steps of manufacturing a semiconductor device. The etching apparatus is used, for example, in both an etching step of forming a semiconductor element such as a MOSFET and an etching step of forming a pad electrode. In the etching step of forming a MOSFET, the etching apparatus is used in an etching step of forming, for example, a gate electrode and a gate insulating film.

Because etching processing using plasma is performed in the etching step, depositions are deposited, for example, over the inner surface of the chamber 2 every time the etching processing is performed. A foreign matter occurs, for example, with the deposited deposition being peeled, and when the foreign matter falls over a semiconductor wafer, the yield of the semiconductor wafer is reduced. When a foreign matter falls particularly in the etching step of forming a gate electrode and a gate insulating film, the characteristics of a semiconductor element are largely deteriorated even if the size of the foreign matter is small. Therefore, in forming a gate electrode and a gate insulating film, the inner surface of the chamber 2 is frequently cleaned. On the other hand, in the etching step of forming, for example, a pad electrode, the characteristics of an element are less influenced even if a foreign matter having a small size falls. Therefore, it is possible to relatively lengthen an interval between the cleaning of the inner surface of the chamber 2. By lengthening the cleaning interval, it is possible to shorten the time required for manufacturing a semiconductor device, which can suppress manufacturing cost.

In Second Embodiment, an etching step of forming a pad electrode, in which there is high possibility that the amount of the generated depositions may be large and the amount of the depositions deposited over the inner surface of the chamber 2 may also be large, will be described as an example. The etching apparatus 1 according to First Embodiment presents cleaning of the chamber 2 or inspection or replacement of a component, as described with reference to FIG. 7. Therefore, it is possible to grasp the timing of the cleaning and that of the inspection or replacement, based on the presentation. As a result, the cleaning interval or/and the inspection/replacement timing can be appropriately set.

Herein, three etching steps out of a plurality of etching steps to be performed when a 90-nm microcomputer semiconductor device is manufactured will be described as an example. In other words, of the semiconductor manufacturing steps, three etching steps to be performed in the step of forming a pad electrode in a metal wiring film will be described as an example.

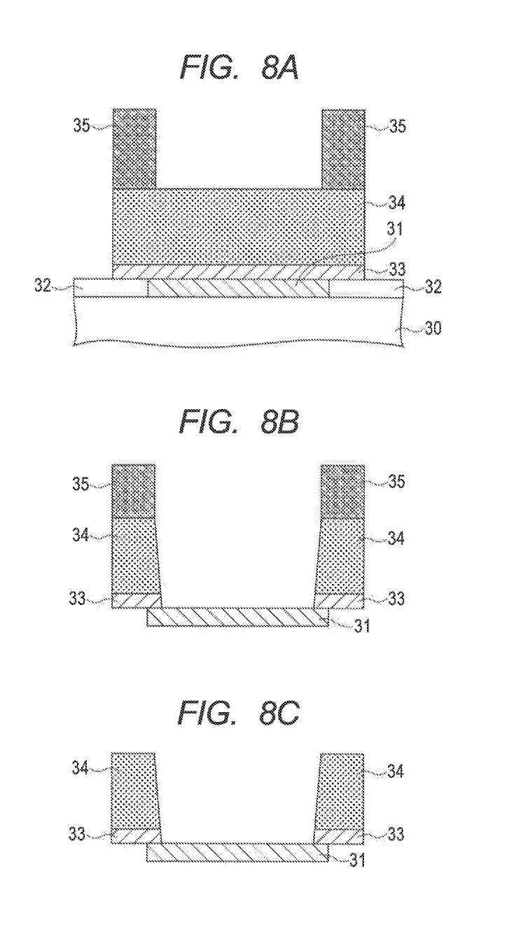

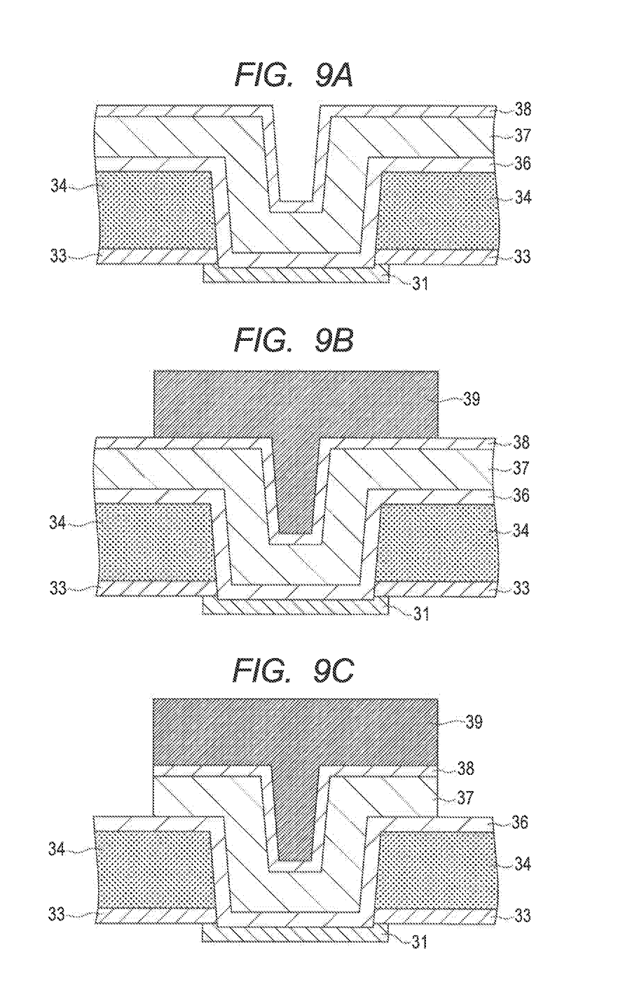

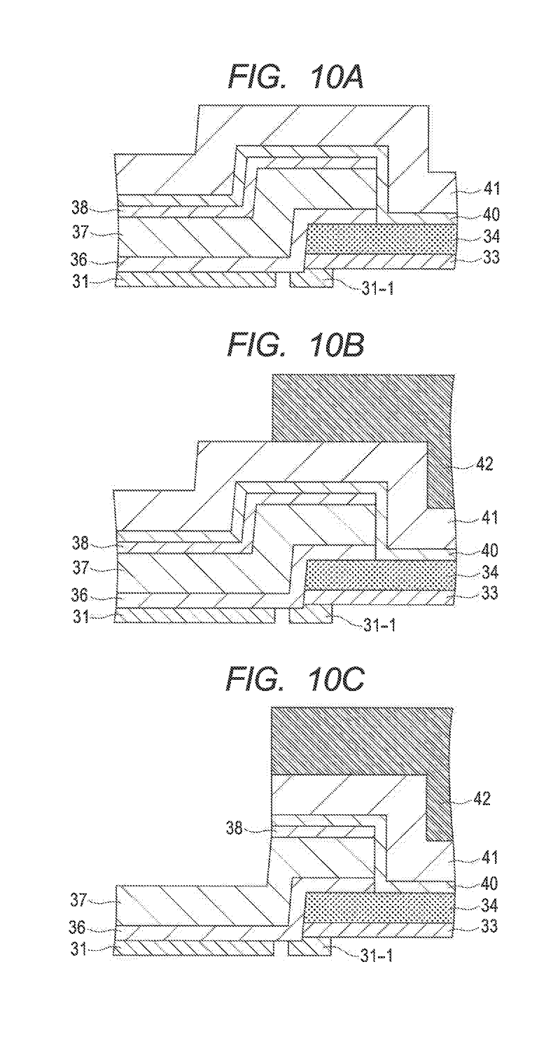

FIGS. 8A to 10C are sectional views illustrating a semiconductor manufacturing method according to Second Embodiment. FIGS. 8A to 8C illustrate a first etching step (VPD etching step) to be performed when a via (through hole) is formed, while FIGS. 9A to 9C illustrate a second etching step (ALP etching step) to be performed when an aluminum film that forms a pad electrode is formed. Further, FIGS. 10A to 10C illustrate a third etching step (PI etching step) to be performed when the pad electrode is shaped. As will be described below, the three etching steps are performed sequentially from the first etching step to the third etching step, and hence FIGS. 8A to 10C illustrate the VPD etching step through the PI etching step.

First, a manufacturing step of forming a through hole in a plurality of films arranged over a metal wiring film will be described with reference to FIGS. 8A to 8C. In FIG. 8A, the reference numeral 30 denotes a semiconductor substrate. A metal wiring film 31 is formed above the semiconductor substrate 30 via a non-illustrated insulating film. An insulating film 32 is formed to interpose the wiring film 31. A silicon nitride film 33 is formed above the wiring film 31, and further a silicon oxide film 34 is formed above the silicon nitride film 33. Herein, the metal wiring film 31 is composed of, for example, copper. Further, the thickness of the silicon nitride film 33 is, for example, 120 nm, and that of the silicon oxide film 34 is, for example, 1000 nm. A resist film 35, formed so as to have an opening matching the opening of the through hole, is formed above the silicon oxide film 34.

The semiconductor substrate having the sectional shape illustrated in FIG. 8A is adsorbed by the electrostatic chuck 8 illustrated in FIG. 1, and hermetically sealed in the chamber 2. In a sealed state, etching processing is performed by using plasma. FIG. 8B illustrates the first etching step in which this etching processing is performed. The silicon oxide film 34 in contact with the opening of the resist film 35 is etched by plasma, and further the silicon nitride film 33 is etched by using the opening of the silicon oxide film 34 formed by the etching as a mask. In FIGS. 8B to 10C, the above semiconductor substrate 30 and insulating layer 32 interposing the wiring film 31 are omitted.

In the step of FIG. 8C, the resist film 35 formed above the silicon oxide film 34 is removed. The silicon nitride film 33 and the silicon oxide film 34, which are arranged above the metal wiring film 31, are etched by the steps of FIGS. 8A to 8C with the use of the resist film 35 as a mask in order to form a through hole, and a predetermined portion of the metal wiring film 32 is exposed via the through hole.

FIGS. 9A to 9C illustrate a step of embedding a metal wiring film in the through hole formed in FIGS. 8A to 8C. In FIG. 9A, the reference numeral 36 denotes a film formed to be embedded in the through hole formed in FIG. 8C. This film 36 is, for example, a titanium nitride/titanium film (hereinafter also simply referred to as a titanium film). A metal wiring film 37 is formed above the titanium film 36, and further a titanium nitride film 38 is formed above the wiring film 37. The wiring film 37 is an aluminum-copper film. The thickness of the above titanium nitride/titanium film 36 is, for example, 200/50 nm, that of the aluminum-copper film 37 is, for example, 1600 nm, and that of the titanium nitride film 38 is, for example, 25 nm. These titanium film 36, aluminum-copper film 37, and the titanium nitride film 38 are sequentially formed to be embedded in the opening in FIG. 8C.

In FIG. 9B, a resist film 39, having a planar shape covering a dent region corresponding to the opening, is formed above the titanium nitride film 38.

Next, a semiconductor substrate having the sectional shape of FIG. 9B is hermetically sealed in the chamber 2 in the same way as described with reference to FIG. 8B. In a sealed state, etching processing is performed by plasma. FIG. 9C illustrates the second etching step of performing the etching processing by plasma. In the second etching step of FIG. 9C, the titanium nitride film 38 and the aluminum-copper film 37, which exist in a region where the resist film 39 is not arranged, are etched by plasma with the use of the resist film 39 as a mask. Thereby, the aluminum-copper film 37 that forms the pad electrode is coupled to the wiring film 31 via the titanium film 36.

FIGS. 10A to 10C illustrate a step of shaping the aluminum-copper film 37 formed in FIGS. 9A to 9C into the shape of the pad electrode.

In the step of FIG. 10A, the resist film 39 illustrated in FIG. 9C is first removed. Further, a silicon oxide film 40 and a silicon nitride film 41 are formed above the titanium nitride film 38. The thicknesses of the silicon oxide film 40 and the silicon nitride film 41 are, for example, 120 nm and 1000 nm, respectively. As a result, the state of the section illustrated in FIG. 10A is obtained. In FIG. 10A, the reference numeral 31-1 denotes a wiring film formed next to the wiring film 31.

After FIG. 10A, a polyimide resin-based PIQ film 42 is formed above the silicon nitride film 41, as illustrated in FIG. 10B. An opening, matching the shape of the pad electrode to be shaped, is formed in the PIQ film.

Next, the semiconductor substrate having the sectional shape illustrated in FIG. 10B is hermetically sealed in the chamber 2, and etching processing is performed by using plasma in the same way as described with reference to FIG. 8B. FIG. 10C illustrates the third etching step of performing this etching processing. In the third etching step, the silicon nitride film 41, the silicon oxide film 40, and the titanium nitride film 38, which are in contact with the opening of the PIQ film, are etched by plasma with the use of the PIQ film 42 as a mask. In this third etching step, part of the aluminum-copper film 37 is also etched.

By the semiconductor manufacturing steps illustrated in FIGS. 8A to 10C, the aluminum-copper film 37 that forms a pad electrode is coupled to the wiring film 31 formed over the semiconductor substrate. This aluminum-copper film 37 is exposed from the PIQ film 42 that is a protective film, and functions as a pad electrode for electrically coupling the wiring (wiring film 31) of the semiconductor device and the outside of the semiconductor device.

FIGS. 9A and 10A correspond to a step of forming an insulating film or the like above the wiring layer 31. Further, FIGS. 9B and 10B correspond to a step of forming a mask for defining a region where etching is to be performed. FIG. 8A corresponds to both the step of forming an insulating film or the like above the wiring layer 31 and the step of forming the mask. FIGS. 8B, 9C, and 10C correspond to an etching step.

In each of the etching steps (the first step to the third step) described with reference to FIGS. 8B, 9C, and 10C, the observation device 11 performs observation and performs detection of abnormal discharge (abnormal discharge detection 21) as described with reference to FIG. 7, and in the case of abnormal discharge, presents a measure. That is, a determination step of determining abnormal discharge and a presentation step of presenting a measure are performed in the etching step.

The invention made by the present inventors has been specifically described above based on preferred embodiments, but it is needless to say that the invention should not be limited to the preferred embodiments and various modifications may be made to the invention within a range not departing from the gist of the invention.

What is claimed is:

1. A semiconductor manufacturing apparatus comprising:
a processing table that is installed in a processing chamber and over which a semiconductor substrate to be subjected to plasma processing is to be mounted; and
an observation device that observes a change in a signal waveform occurring over the processing table during the plasma processing,
wherein the observation device determines abnormal discharge in the processing chamber based on a change pattern of the signal waveform.

2. The semiconductor manufacturing apparatus according to claim 1,
wherein the processing table includes an electrostatic chuck to which a first voltage for adsorbing the semiconductor substrate is to be supplied, and
wherein the observation device observes a voltage change superimposed on the first voltage supplied to the electrostatic chuck.

3. The semiconductor manufacturing apparatus according to claim 2,
wherein the processing table includes an electrode to which a second voltage for generating plasma is to be supplied, and
wherein the observation device observes a voltage change superimposed on the first voltage and the second voltage.

4. The semiconductor manufacturing apparatus according to claim 2,
wherein the change pattern is a pattern in which the signal waveform exceeds a predetermined threshold value in a predetermined period of time.

5. The semiconductor manufacturing apparatus according to claim 4,
wherein the semiconductor manufacturing apparatus includes a component that is installed to surround the semiconductor substrate when the semiconductor substrate is viewed from its main surface side and that is arranged such that a main surface of the component extends along the main surface of the semiconductor substrate.

6. The semiconductor manufacturing apparatus according to claim 5,
wherein the observation device estimates a place of the processing chamber where abnormal discharge is occurring from a difference in the change pattern of the signal waveform.

7. The semiconductor manufacturing apparatus according to claim 6,
wherein when the number of times when the signal waveform exceeds a predetermined threshold value is smaller than a predetermined number of times, the observation device specifies the change pattern as a first abnormal discharge pattern,
wherein when the number of times when the signal waveform exceeds a predetermined threshold value is larger than the predetermined number of times, the observation device specifies the change pattern as a second abnormal discharge pattern,
wherein when the signal waveform exceeds a predetermined threshold value and an envelope of waveforms that exceed the predetermined threshold value rises, the observation device specifies the change pattern as a third abnormal discharge pattern, and
wherein the observation device estimates a place where abnormal discharge is occurring, depending on which one of the first abnormal discharge pattern, the second abnormal discharge pattern, and the third abnormal discharge pattern the change pattern of the signal waveform is.

8. The semiconductor manufacturing apparatus according to claim 7,
wherein the observation device cyclically observes the signal waveform with the predetermined period of time as a cycle.

9. The semiconductor manufacturing apparatus according to claim 8,
wherein the processing chamber is a processing chamber of an apparatus for performing etching processing.

10. A semiconductor manufacturing method comprising the steps of:
forming an insulating film above a wiring layer formed over a semiconductor substrate;
etching the insulating film by plasma processing; and
determining abnormal discharge based on a change pattern of a signal waveform occurring, in the etching step, over a processing table over which the semiconductor substrate is mounted.

11. The semiconductor manufacturing method according to claim 10,
wherein the wiring layer is a metal wiring layer to be coupled to a pad electrode.
